(19) United States
(12) Patent Application Publication
(10) Pub. No.: US 2026/0072085 A1
(43) Pub. Date: Mar. 12, 2026

(54) JIG FOR MEASURING THREE-ELECTRODE VOLTAGES

(71) Applicants: Samsung SDI Co., Ltd., Yongin-si (KR); Research & Business Foundation SUNGKYUNKWAN UNIVERSITY, Suwon-si (KR)

(72) Inventors: Ji Young LEE, Yongin-si (KR); Ho Seok PARK, Suwon-si (KR); Jun Su KIM, Suwon-si (KR); Yoon Bin KIM, Yongin-si (KR); Yun Sang JOE, Yongin-si (KR); Ra Kyung KIM, Suwon-si (KR); Chan Min PARK, Suwon-si (KR)

(21) Appl. No.: 19/280,468

(22) Filed: Jul. 25, 2025

(30) Foreign Application Priority Data
Sep. 10, 2024 (KR) 10-2024-0122919

(51) Int. Cl. G01R 31/36; G01N 27/30; G01R 31/385; H01M 10/42; H01M 10/48

(52) U.S. Cl. CPC G01R 31/3644; G01N 27/30; G01R 31/385; H01M 10/4285; H01M 10/484

(57) ABSTRACT

A jig for measuring three electrode voltages includes: a jig body having a receiving portion for a secondary battery; a jig door for sealing the receiving portion; a positive electrode on the receiving portion, electrically connected to a positive electrode tab, and protruding outwardly; a negative electrode on the receiving portion of the jig body, being in contact with and electrically connected to a conductive member electrically connected to the secondary battery, and protruding outwardly; and a reference electrode inserted into a winding core of an electrode assembly of the secondary battery in the receiving portion while extending through a top plate of the jig body and protruding to an upper portion of the jig body. The reference electrode comprises a metal wire and a metal cap wrapping around the metal wire, and a length of the metal cap is in a range of 15 mm to 20 mm.

### CROSS-REFERENCE TO RELATED APPLICATION

The present application claims priority to and the benefit of Korean Patent Application No. 10-2024-0122919, filed on Sep. 10, 2024, in the Korean Intellectual Property Office, the entire disclosure of which is incorporated herein by reference.

### BACKGROUND

### 1. Field

Aspects of embodiments of the present disclosure relate to a jig for measuring three electrode voltages.

### 2. Description of the Related Art

Generally, the electrode potential of a battery is measured to verify the performance of a newly developed and/or manufactured battery. A method for measuring electrode potentials of a three-electrode system consisting of a reference electrode, a working electrode, and a potential electrode is primarily used.

A reference electrode is an electrode that is used to make a battery circuit for measuring an electrode potential in combination with electrodes that constitute a battery or an electrode where electrolysis takes place and acts as a standard potential when measuring a relative value of an electrode potential.

The reference electrode must satisfy the requirements including following the Nernst equilibrium theory as a reversible electrode potential (an electrode in a reversible state), having non-polarizable characteristics that always maintain a constant potential value, having as small a potential difference between liquids as possible, having a small potential change even when the temperature changes, and exhibiting a constant potential value at a constant temperature.

In this regard, in the field of secondary batteries, which has been rapidly growing recently, electrode potential measurements are being conducted extensively for the development of new batteries and performance improvement of existing batteries. To measure an electrode potential of a secondary battery, conventional methods are generally used. For example, when measuring the performance of a newly developed positive electrode active material, electrode potentials may be measured by placing an electrolyte in a container and installing a positive electrode coated with a positive electrode active material as a working electrode, a reference electrode, and a negative electrode as a potential electrode. However, this method suffers the following shortcomings.

First, results that do not match the electrode potential in an actual battery may be obtained. Generally, in a secondary battery, an electrode assembly having a structure consisting of a positive electrode/separator/negative electrode is impregnated with an electrolyte and is contained in a sealed case (can, pouch, etc.), and various other battery components are installed therein. Therefore, the internal environment of an actual secondary battery is quite different from that under experimental conditions, and thus, there may exist a difference in comparison with the electrode potential measured under the experimental conditions, which are very simplified.

Second, it is impossible to simultaneously measure the potential changes of positive and negative electrodes during actual charging and discharging.

Third, to measure an electrode potential, a manufactured battery must be completely disassembled. In cases where periodic testing is performed for the purpose of quality assessment of mass-produced batteries, completely disassembling batteries is time-consuming, and as described above, changes in the actual conditions of batteries may be caused, making it difficult to obtain accurate results.

Fourth, under various experimental conditions to measure various properties required for a battery, it is not easy to measure an electrode potential. Secondary batteries must satisfy various requirements, including exhibiting high-temperature safety and safety during needle (or nail) penetration, and the electrode potentials must be measured under the experimental conditions to verify whether or not these requirements are met.

To measure the potential of an electrode in a solution, the potential difference must be measured in an equilibrium state in which the actual current between a working electrode and a reference electrode is almost negligible.

However, when an external voltage is applied between electrodes, a voltage drop occurs due to the resistance between the electrodes, causing the electrode potential of the reference electrode to deviate from the equilibrium state and, thus, errors may occur. In addition, when evaluating a battery cell to measure the electrode potential of a three-electrode system, as described above, methods for measuring the electrode potential by immersing a jelly-roll in a solution contained in a beaker or after decomposing a jelly-roll into a bi-cell type, are primarily used.

However, the aforementioned measurement method using a beaker or a bi-cell type is problematic in that the manufacture is not easy and is time consuming.

### SUMMARY

Embodiments of the present disclosure provide a jig for measuring three electrode voltages, which can measure charge and discharge voltages of a secondary battery in an environment similar to that of an actual secondary battery by minimizing air contact and electrolyte use of a battery cell.

In addition, embodiments of the present disclosure provide a jig for measuring three electrode voltages, which can measure the charge and discharge voltages of a secondary battery under conditions similar to those of an actually used secondary battery, thereby reducing errors that may occur when evaluating the secondary battery.

A jig for measuring three electrode voltages, according to an embodiment of the present disclosure, includes: a jig body having a receiving portion for mounting a secondary battery having an electrode assembly inside a case; a jig door for opening or closing a first surface forming the receiving portion; a positive electrode mounted on an upper portion of the receiving portion of the jig body, electrically connected to a positive electrode tab protruding toward an upper portion of the secondary battery mounted on the receiving portion, and having a portion protruding outwardly; a negative electrode mounted on the receiving portion of the jig body, being in contact with and electrically connected to a conductive member electrically connected to the case of the secondary battery, and having a portion protruding outwardly; and a reference electrode inserted into an electrolyte of a winding core of the electrode assembly of the secondary battery mounted in the receiving portion while extending through a top plate of the jig body and protruding to an upper portion of the jig body. The reference electrode includes a metal wire and a metal cap wrapping around one side of the metal wire and is inserted into the winding core of the secondary battery, and a length of the metal cap is in a range of 15 mm to 20 mm.

A length of the reference electrode inserted into the secondary battery may reach 30% to 50% of a total height of the secondary battery.

The metal cap may include lithium, and the metal wire may include copper.

The top plate of the jig body may have a reference groove having a depth from an upper surface to a lower side and a reference hole extending through the top plate from a center of the reference groove to the lower side.

The jig may further include a protective tube. The protective tube may include a body part having a diameter corresponding to an inner diameter of the reference groove and an extension part extending downwardly from a center of the body part and having a diameter corresponding to an inner diameter of the reference hole.

A length of the protective tube inserted into the secondary battery may reach 20% to 30% of a total height of the secondary battery.

The protective tube may further include an O-ring on an outer surface of the body part.

The protective tube may further include a penetration pipe extending between upper and lower sides of the top plate, and the reference electrode may protrude upwardly and downwardly through the penetration pipe of the protective tube.

The jig may further include a hole cover coupled to an upper side of the top plate and having a reference hole for exposing and receiving a portion of the reference electrode to the outside.

The hole cover may have a reference groove having a depth upward from a lower surface and a reference hole extending through the hole cover upwardly from a center of the reference groove of the hole cover.

The protective tube may include a body part between the top plate of the jig body and the hole cover.

The jig door may have a flat plate shape, one edge of an inner surface may be coupled to the jig body by a hinge, and a first surface of the jig body may be configured to be opened and closed by rotation.

The jig door may have a receiving portion for receiving a portion of the secondary battery mounted in the receiving portion of the jig body on an inner surface.

The jig may further include rubber packing provided along an inner edge of the jig door, and the rubber packing may be between the inner surface of the jig door and the first surface of the jig body.

In the jig door, a spring press may be provided on an inner surface in contact with the positive electrode and the positive electrode tab of the secondary battery.

The jig body may have a rectangular parallelepiped shape.

The conductive member may cover an inner surface of the receiving portion and may extend to partially cover the first surface of the jig body.

The positive electrode may be mounted on the first surface on an upper side of the receiving portion of the jig body.

An electrolyte may be added into the case of the secondary battery, and an amount of electrolyte added may be in a range of 0.8 ml to 1.0 ml.

In the jig for measuring three electrode voltages, according to embodiments of the present disclosure, air contact and electrolyte use of a battery cell are reduced or minimized such that the charge and discharge voltages of a secondary battery can be measured in an environment similar to that of an actual secondary battery.

That is, a jig for measuring three electrode voltages, according to embodiments of the present disclosure, can measure the charge and discharge voltages of a secondary battery under conditions similar to those of an actually used secondary battery, thereby reducing errors in evaluating the secondary battery.

In more detail, because the charge and discharge voltages of a secondary battery can be measured after mounting the secondary battery with only a cap assembly removed in a jig for measuring three electrode voltages, the time required to disassemble the secondary battery can be reduced. In addition, because the charge and discharge voltages of a secondary battery can be measured in an environment similar to that of an actual secondary battery, the reliability of the results of evaluating a secondary battery can be improved.

### BRIEF DESCRIPTION OF THE DRAWINGS

FIG. 1 is a perspective view of a jig for measuring three electrode voltages according to an embodiment of the present disclosure.

FIGS. 2A and 2B are enlarged front views of a protective tube and a protective tube coupled to a reference electrode in the jig for measuring three electrode voltages shown in FIG. 1.

FIG. 3 is a front view showing the protective tube coupled to the reference electrode shown in FIG. 2B mounted on a hole cover.

FIG. 4 is a cross-sectional view taken along the line 4-4′ in FIG. 1.

FIGS. 5A and 5B are perspective views showing before and after, respectively, a cap is separated from a secondary battery subjected to electrode potential measurement in the jig for measuring three electrode voltages shown in FIG. 1.

FIG. 6 is an enlarged view of one end of the reference electrode shown in FIG. 1.

FIGS. 7A to 7C are graphs of the results of measuring charge and discharge voltages over time of an actual secondary battery and a secondary battery for evaluation mounted on the jig for measuring three electrode voltages shown in FIG. 1.

FIGS. 8A to 8D are graphs showing capacity change rates according to the voltage change rates of an actual secondary battery and a secondary battery for evaluation mounted on the jig for measuring three electrode voltages shown in FIG. 1.

FIGS. 9A to 9D are graphs showing the results of measuring the charge and discharge voltages over time according to the amount of electrolyte injected of an actual secondary battery and a secondary battery for evaluation mounted on the jig for measuring three electrode voltages shown in FIG. 1.

FIG. 10 are photographs showing the states of a secondary battery for evaluation and a jig body and a jig door in a jig for measuring three-electrode voltages after measuring the charge/discharge voltage over time after an electrolyte is injected into the secondary battery for evaluation.

FIG. 11 is a cross-sectional view showing the height of a reference electrode and the height of a protective tube according to the height of a secondary battery and a jig for measuring three electrode voltages.

### DETAILED DESCRIPTION

Hereinafter, embodiments of the present disclosure will be described, in detail, with reference to the accompanying drawings.

Embodiments of the present disclosure are described to more completely explain aspects and features of the present disclosure to those skilled in the art, and the following embodiments may be modified in various other forms. The present disclosure, however, may be embodied in many different forms and should not be construed as being limited to the embodiments set forth herein. Rather, these embodiments are provided so that this disclosure will be thorough and complete and will convey the aspects and features of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

Embodiments of the present disclosure will now be described, in detail, with reference to the attached drawings so that a person skilled in the art to which the present disclosure belongs can easily practice the present disclosure.

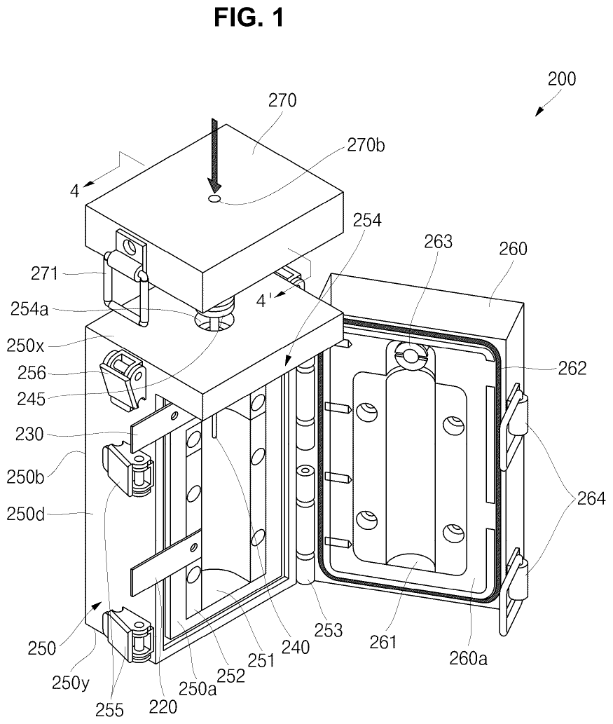

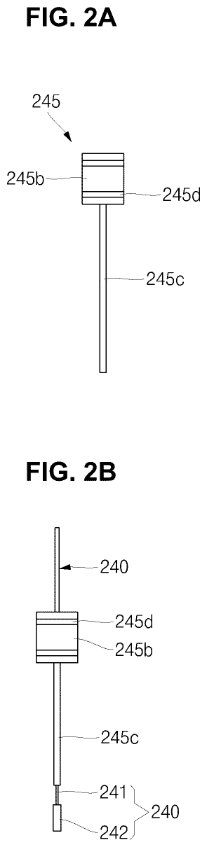

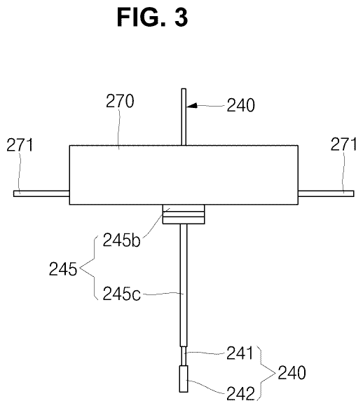

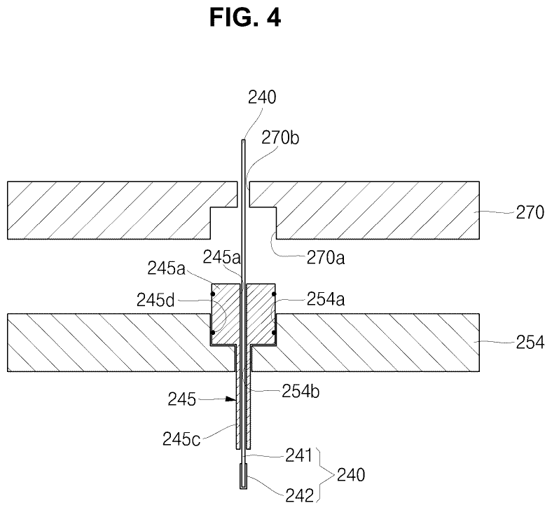

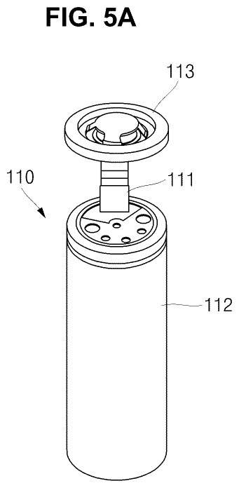

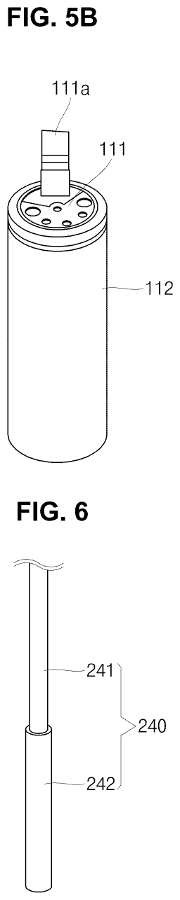

FIG. 1 is a perspective view of a jig for measuring three electrode voltages according to an embodiment of the present disclosure, FIGS. 2A and 2B are enlarged front views of a protective tube and a protective tube coupled to a reference electrode in the jig for measuring three electrode voltages shown in FIG. 1, FIG. 3 is a front view showing a configuration in which the protective tube coupled to the reference electrode shown in FIG. 2B is mounted on a hole cover, FIG. 4 is a cross-sectional view taken along the line 4-4′ in FIG. 1, and FIGS. 5A and 5B are perspective views showing states before and after, respectively, a cap is separated from a secondary battery subjected to electrode potential measurement in the jig for measuring three electrode voltages shown in FIG. 1.

Hereinafter, the jig 200 for measuring three electrode voltages according to an embodiment of the present disclosure will be described with reference to FIGS. 1 to 5B.

The jig 200 for measuring three electrode voltages, according to an embodiment of the present disclosure, may include a jig body 250 in which the secondary battery 110 is received (or accommodated), a jig door 260 sealing the jig body 250, a negative electrode 220 and a positive electrode 230 mounted on the jig body 250, a protective tube 245 and a reference electrode 240 coupled through (e.g., extending through) the upper side of the jig body 250, and a hole cover 270 coupled to the upper portion of the jig body 250. Here, the secondary battery 110 is a separate component from the jig 200 for measuring three electrode voltages and can be mounted in or separated from the jig 200 for measuring three electrode voltages.

Here, the secondary battery 110 may be manufactured such that an electrode assembly 111 having a coiled (or wound) structure is received (or accommodated) in a cylindrical case 112, an electrolyte is injected into the case 112, a cap assembly 113 equipped with a positive electrode terminal is coupled at an open top end of the case 112. According to embodiments of the present disclosure, the cap assembly 113 may be removed from the secondary battery 110 being subjected to three-electrode potential measurement before being received in a receiving portion 251 of the jig 200. For example, the secondary battery 110 may include the electrode assembly 111 received in the case 112.

The electrode assembly 111 includes a negative electrode plate coated with a negative electrode active material, a positive electrode plate coated with a positive electrode active material, and a separator interposed between the negative electrode plate and the positive electrode plate allowing lithium ions to move therebetween while preventing shorts between the negative electrode plate and the positive electrode plate. The electrode assembly 111 may be formed by winding stacked arrangement of a negative electrode plate, a separator, a positive electrode plate, and a separator in a substantially cylindrical shape. The electrode assembly 111 may be wound with the separator extending further in the winding front direction than the negative electrode plate and the positive electrode plate. That is, in the electrode assembly 111, the separator may be positioned on a winding core.

In the electrode assembly 111, a positive electrode tab 111a electrically connected to a positive electrode plate may protrude upwardly therefrom and a negative electrode tab electrically connected to the negative electrode plate may protrude downwardly therefrom. Here, the negative electrode tab may be connected and bonded to the bottom of a case 112 by welding. Therefore, the case 112 may act as a negative electrode.

The jig body 250 has a roughly rectangular parallelepiped shape and may have a top surface 250x and a bottom surface 250y opposite to the top surface 250x. The jig body 250 may also have a first surface 250a coupled to (e.g., facing or sealing with) the jig door 260 and a second surface 250b opposite to the first surface 250a. In addition, the jig body 250 may have a first side surface and a second side surface 250d connecting (or extending between) the first surface 250a and the second surface 250b to each other.

The jig body 250 may be made of an insulating material. For example, the jig body 250 may be made of polyethylene terephthalate (PET) or an equivalent material thereof. The jig body 250 may have a receiving portion 251 for receiving the cylindrical secondary battery 110 with the cap assembly 113 removed therefrom inwardly from the first surface 250a, which is flat. The receiving portion 251 may have a semi-cylindrical shape corresponding to the shape of the side surface of the secondary battery 110. The receiving portion 251 may be located approximately at the center of the first side surface 250a.

The jig body 250 may further include a jig door 260 and a fixing means 253 for rotation and fixation at one edge at where the first side surface 250a and the first side surface are connected. Here, the fixing means 253 may be a hinge. Thus, the jig door 260 is fixed to one edge of the jig body 250 and may open or close the first side 250a by rotation.

The jig body 250 may further include a conductive member 252 provided to cover the inner surface of the receiving portion 251. The conductive member 252 may be provided as a metal plate shaped to correspond to the inner surface of the receiving portion 251. The conductive member 252 may extend further toward the other edge at where the first side 250a of the jig body 250 and the second side surface 250d are connected to cover a portion of the first side 250a. The conductive member 252 may be electrically connected to the negative electrode 220.

The negative electrode 220 may be a flat metal plate. The negative electrode 220 may have one side in contact with the first side 250a of the jig body 250 and another side exposed to the outside. Of course, when the jig door 260 is coupled to the jig body 250, the other side of the negative electrode 220 may be in contact with the inner surface of the jig door 260. The negative electrode 220 may have one end electrically and mechanically coupled to the conductive member 252 covering the first side 250a of the jig body 250. The negative electrode 220 may be mounted on and extending from the first surface 250a of the jig body 250 and may have the other end protruding toward the other side edge connected to the second side surface 250d. The negative electrode 220 and the conductive member 252 may be made of the same metal. For example, the negative electrode 220 and the conductive member 252 may be made of aluminum (Al), copper (Cu), nickel (Ni), gold (Au), platinum (Pt), or an equivalent metal thereof. In one embodiment, the negative electrode 220 and the conductive member 252 may be made of nickel (Ni) to reduce contact resistance with the case 112, which is often made of nickel (Ni).

When the secondary battery 110 is coupled into the receiving portion 251 of the jig body 250, the case 112 of the secondary battery 110 and the conductive member 252 may be in contact with and electrically connected to each other. That is, the negative electrode 220 may be electrically connected to the case 112 of the secondary battery 110. Here, the secondary battery 110 may be the same as the secondary battery 110 from which the cap assembly 113 has been removed as shown in FIG. 5B. The secondary battery 110 may be filled with an electrolyte before being inserted into the receiving portion 251.

In addition, the jig body 250 may be equipped with a positive electrode 230 on the upper side of the first surface 250a. The positive electrode 230 may be a flat metal plate. One side of the positive electrode 230 may be in contact with the first surface 250a of the jig body 250, and another side thereof may be exposed to the outside. Of course, when the jig door 260 is coupled to the jig body 250, the other side of the positive electrode 230 may be in contact with the inner surface of the jig door 260. The positive electrode 230 may have one end fixed to the upper side of the first surface 250a of the jig body 250 with the other end protruding toward the other side edge side at where the first surface 250a of the jig body 250 and the second side surface 250d are connected. The positive electrode 230 may be approximately parallel to the negative electrode 220. The positive electrode 230 may be spaced apart from the conductive member 252. The positive electrode 230 may be made of aluminum (Al), copper (Cu), nickel (Ni), gold (Au), platinum (Pt), or an equivalent metal thereof. In one embodiment, the positive electrode 230 may be made of aluminum (Al) to reduce contact resistance with the positive electrode tab 111a, which is often made of aluminum (Al). When the secondary battery 110 is coupled into the receiving portion 251 of the jig body 250, the positive electrode tab 111a of the secondary battery 110 may be in contact with and electrically connected to the positive electrode 230.

The top surface 250x of the jig body 250 may protrude further outwardly than the first surface 250a. In one embodiment, the jig body 250 may further include a top plate 254 having a flat plate shape extending to cover the top surface of the jig door 260 when the jig door 260 is coupled to the first surface 250a. The top surface of the top plate 254 may be coplanar with the top surface 250x of the jig body 250.

The jig body 250 may have a reference groove 254a having a depth (e.g., a predetermined depth) downward from the top surface of the top plate 254. The reference groove 254a may be located approximately at the center of the top plate 254. In addition, a reference hole 254b formed downward approximately from the center of the reference groove 254a and penetrating (or extending through) the top plate 254 may be provided. The inner diameter of the reference groove 254a may be larger than the inner diameter of the reference hole 254b. The inner diameters of the reference groove 254a may be the same in the depth direction of the reference groove 254a and the inner diameters of the reference hole 254b may be the same in the depth direction of the reference hole 254b.

The reference hole 254b may be located at the upper side of the receiving portion 251. The planar shapes of the reference groove 254a and the reference hole 254b may be circular. The protective tube 245 may be mounted on the reference groove 254a and the reference hole 254b.

The protective tube 245, mounted in the reference groove 254a and the reference hole 254b of the jig body 250, may penetrate (or may extend through) the top plate 254. The upper end of the protective tube 245 may be exposed to the upper side of the top plate 254, and the lower end thereof may be positioned within the winding core of the secondary battery 110 mounted in the receiving portion 251. The upper end of the protective tube 245 may be larger than the lower end.

The protective tube 245 may include a cylindrical body part 245b having a diameter (e.g., a predetermined diameter) and a cylindrical extension part 245c extending downwardly from the center of the bottom surface of the body part 245b and having a smaller diameter than the body part 245b. For example, the protective tube 245 may have a stepped outer surface between the body part 245b and the extension part 245c. The diameter of the body part 245b may correspond to the inner diameter of the reference groove 254a, and the diameter of the extension part 254c may correspond to the reference hole 254b. Of course, if the diameter of the protective tube 245 is smaller than the inner diameters of the reference groove 254a and the reference hole 254b, the protective tube 245 may be easily mounted on the jig body 250. In addition, an O-ring 245d may be further provided on the outer surface of the body part 245b of the protective tube 245. The protective tube 245 may be provided with the O-ring 245d to improve sealing with the reference groove 254a. The protective tube 245 may be provided with one or more O-rings 245d on the body part 245b, but the present disclosure is not limited thereto.

In addition, the protective tube 245 may include a penetration pipe 245a penetrating between the upper and lower parts. The reference electrode 240 may be inserted into the receiving portion 251 of the jig body 250 through the penetration pipe 245a of the protective tube 245. That is, when the secondary battery 110 is mounted in the receiving portion 251 of the jig body 250, the reference electrode 240 may be inserted into the electrolyte of the winding core of the secondary battery 110. Here, the protective tube 245 may make it easier to insert the reference electrode 240 into the reference hole 254b provided in the jig body 250. In addition, the protective tube 245 may be coupled and fixed to the top plate 254 of the jig body 250 by the body part 245b of the protective tube 245. The protective tube 245 may be made of an insulating material. In one embodiment, the protective tube 245 may be made of polyetheretherketone (PEEK) or an equivalent material.

The reference electrode 240 may have a metal cap 242 placed on one end of a metal wire 241 as shown in, for example, FIG. 6. The metal wire 241 may be made of copper, and the metal cap 242 may be made of lithium. For example, the reference electrode 240 may be shaped such that lithium is wrapped around one end of a copper wire. The metal cap 242 located at one end of the reference electrode 240 may be inserted into the winding core of the electrode assembly 111 through the penetration pipe 245a of the protective tube 245. The separator is located in the winding core of the electrode assembly 111 so that the reference electrode 240 may not be in electrical contact with the electrode assembly 111. The reference electrode 240 may have the metal wire 241 protrude upwardly from the protective tube 245 and the metal cap 242 protrude downwardly from the protective tube 245. The lower end of the reference electrode 240, where the metal cap 242 is located, may be positioned inside the receiving portion 251 of the jig body 250.

The jig body 250 may be further provided with a coupling means 255 for coupling and fixing the jig door 260 to the second surface 250b. The coupling means 255 may be locking hinges or toggle clamps. In FIG. 1, the jig body 250 is shown as having two coupling means 255, but the number of coupling means 255 may be changed in various manners to one or more depending on the convenience of a user.

The jig door 260 has a flat plate shape, and one edge thereof may be coupled to the jig body 250 by the fixing means 253. Of course, the jig door 260 may further include a combining means 264 mounted on the other edge thereof. The combining means 264 may cooperate with the coupling means 255, for example, the combining means 264 may be a latch. The jig door 260 may rotate by the fixing means 253, and the first surface 250a of the jig body 250 may be opened or covered.

The jig door 260 may have an outer surface that is the opposite surface to a flat inner surface 260a. The inner surface 260a of the jig door 260 may be in contact with or in close contact with the first surface 250a of the jig body 250. The inner surface 260a of the jig door 260 may be provided with a receiving portion 261 for partially accommodating a secondary battery 110 mounted in the receiving portion 251 of the jig body 250. The shape of the receiving portion 261 of the jig door 260 may correspond to that of the receiving portion 251 of the jig body 250. That is, when the inner surface 260a of the jig door 260 is coupled to the first surface 250a of the jig body 250, a portion of the secondary battery 110 mounted in the receiving portion 251 of the jig body 250 can be inserted into the receiving portion 251 of the jig door 260. Here, the receiving portion 261 of the jig door 260 may have a semi-cylindrical shape corresponding to the shape of the side surface of the secondary battery 110.

The jig door 260 may have rubber packing 262 along the edge of the inner surface 260a. The rubber packing 262 may be interposed between the inner surface 260a of the jig door 260 and the first surface 250a of the jig body 250 when the inner surface 260a of the jig door 260 is coupled thereto to improve the sealing force of the receiving portion 251, 261. In addition, the jig door 260 may further be provided with a spring press 263 on the inner surface 260a that comes into contact with the positive electrode 230 and the positive electrode tab 110a of the secondary battery 110. Here, the spring press 263 may press the positive electrode tab 110a of the secondary battery 110 to facilitate contact with the positive electrode 230. That is, the contact resistance between the positive electrode tab 110a of the secondary battery 110 and the positive electrode 230 can be reduced by the spring press 263, and the electrical connection can be facilitated.

In addition, the jig door 260 may have the combining means 264 at a corresponding position to be coupled and fixed with the coupling means 255 of the jig body 250. The jig door 260 may be coupled to the jig body 250 at one edge by the fixing means 253, and the combining means 264 may be mounted on a side adjacent to the other edge. In one embodiment, the coupling means 255 of the jig body 250 and the combining means 264 of the jig door 260 may be mounted spaced apart from each other so as not to come into contact with the negative electrode 220 and the positive electrode 230. The space between the jig body 250 and the jig door 260 may be sealed by the coupling between the combining means 264 of the jig door 260 and the coupling means 255 of the jig body 250. That is, when the secondary battery 110 is accommodated between the jig body 250 and the jig door 260, it can be positioned within the sealed receiving portion 251, 261.

The negative electrode 220 and the positive electrode 230 may be exposed and protrude to the other side between the jig body 250 and the jig door 260. In addition, the reference electrode 240 may be exposed and protrude to the top plate 254 of the jig body 250.

The hole cover 270 may be combined on the upper part of the top plate 254 of the jig body 250. The hole cover 270 has an approximately square plate shape and may be sized to correspond to top plate 254 of the jig body 250. In addition, the hole cover 27 may have a reference groove 270a having a certain depth upward from the bottom surface of the hole cover 270. In addition, the hole cover 270 may further be provided with a reference hole 270b penetrating (or extending through) the hole cover 270 at approximately the center of the reference groove 270a. The reference groove 270a and the reference hole 270b of the hole cover 270 may be symmetrical to each other with respect to the reference groove 254a and the reference hole 254b of the jig body 250. Of course, the inner diameter of the reference groove 270a and the reference hole 270b of the hole cover 270 may correspond to the reference groove 254a and the reference hole 254b of the jig body 250.

The body part 245b of the protective tube 245 may be inserted into the reference groove 270a of the hole cover 270 and the reference groove 254a of the jig body 250. In addition, the reference electrode 240 protruding upwardly from the protective tube 245 through the reference hole 270b of the hole cover 270 may be exposed and protrude therefrom.

The hole cover 270 may be coupled to the jig body 250 by a coupling means 271. Here, the coupling means 271 may be mounted symmetrically to the side surface of the hole cover 270. The coupling means 271 may be a hook or latch. Of course, the jig body 250 may also be provided with a coupling means 256 positioned to correspond to the hole cover 270. The coupling means 256 may be a hook or latch. That is, the hole cover 270 may be coupled to the jig body 250 by the coupling means 256, 271, thereby fixing the protective tube 245 to the jig body 250.

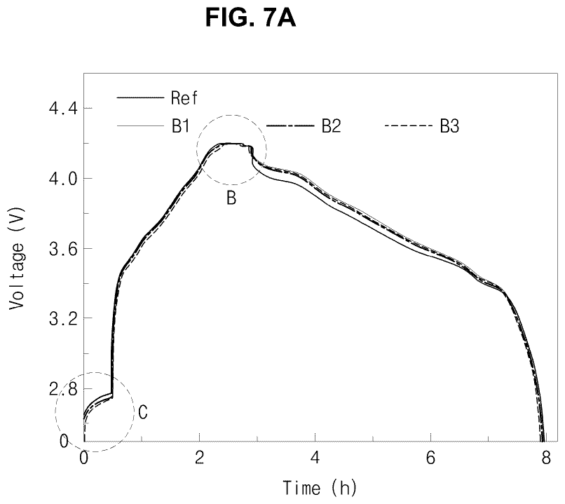

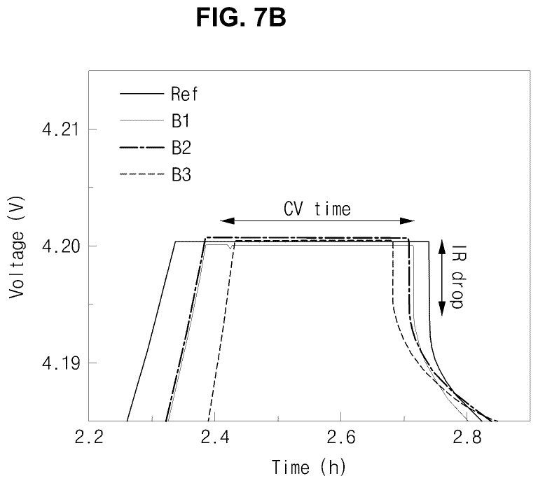

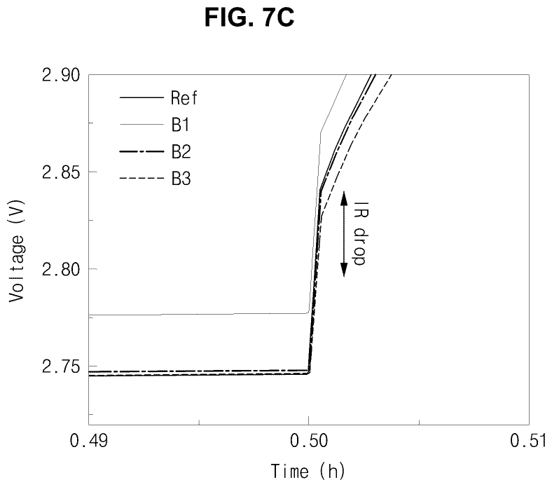

Referring to FIG. 7A, the results of measuring the charge and discharge voltages of an actual secondary battery and a secondary battery mounted on the jig 200 for measuring three electrode voltages shown in FIG. 1 over time are shown. In addition, FIG. 7B is an enlarged view of the portion B in FIG. 7A, and FIG. 7C is an enlarged view of the portion C in FIG. 7A.

Here, the actual secondary battery and the secondary battery mounted on the jig 200 for measuring three electrode voltages (hereinafter referred to as “secondary battery for evaluation”) are secondary batteries having the same capacity manufactured by the same manufacturing process. In addition, the jig 200 for measuring three electrode voltages may be connected to a three-electrode charger/discharger through the negative electrode 220, the positive electrode 230, and the reference electrode 240 electrically connected to the secondary battery for evaluation.

For the secondary battery for evaluation, in the reference electrode 240, when the length of the metal cap 242 is in a range of about 1 cm to about 3 cm, the optimal length of the metal cap 242 may be derived by confirming the similarity between the charge and discharge voltages (hereinafter, “charge/discharge graph”) over time and the charge/discharge graph of an actual secondary battery. Here, the length of the metal cap 242 may be the length in the direction in which the reference electrode 240 extends. In addition, the metal cap 242 may be made of lithium (Li), and the metallic wire 241 may be made of copper (Cu).

Hereinafter, the secondary battery for evaluation with a metal cap having a length of 1 cm is referred to as a first secondary battery B1 for evaluation, the secondary battery for evaluation with a metal cap having a length of 2 cm is referred to as a second secondary battery B2 for evaluation, and the secondary battery for evaluation with a metal cap having a length of 3 cm is referred to as a third secondary battery B3 for evaluation.

Here, the charge/discharge graph shown in FIG. 7A shows the charge and discharge voltage values measured over time when five charge/discharge cycles were performed for each of the actual secondary battery and the secondary battery for evaluation. In addition, the actual secondary battery and the secondary battery for evaluation were charged and discharged at a voltage between 2.5 V and 4.2 V, and the charge was performed at 0.5 C and the discharge was performed at 0.2 C. Here, C may refer to the capacity of the battery.

FIG. 7B shows the charge/discharge graph of the actual secondary battery Ref and secondary batteries B1, B2, and B3 for evaluation in the section where they are charged at a constant voltage (CV). Here, it can be seen that as the length of the metal cap increases, the section where the batteries are charged at the constant voltage (CV) gradually decreases. That is, the charge/discharge graph of the third secondary battery B3 for evaluation shows that the constant voltage charging time is further reduced compared to the charge/discharge graph of the first secondary battery B1 for evaluation and the charge/discharge graph of the second secondary battery B2 for evaluation, suggesting that a greater difference may exist between the actual secondary battery Ref and the third secondary battery B3 for evaluation. In addition, the charge/discharge graph of the third secondary battery B3 for evaluation shows that immediately after CV charging, the voltage drop (IR Drop) during discharge is reduced, resulting in a greater difference from the charge/discharge graph (Ref) of the actual secondary battery.

FIG. 7C shows the charge/discharge graph of the actual secondary battery and the secondary batteries B1, B2, and B3 for evaluation at the section where charging starts. In FIG. 7C, in the case of the charge/discharge graph of the first secondary battery B1 for evaluation, it can be seen that the value at which the charging starts is increased compared to the values from the charge/discharge graphs of the actual secondary battery, the second secondary battery B2 for evaluation, and the third secondary battery B3 for evaluation. That is, the charge/discharge graph of the first secondary battery B1 for evaluation shows that as the charge/discharge cycle is repeated, the charging start voltage increases, resulting in a large difference in the charging start voltage between the values from the charge/discharge graph of the first secondary battery B1 for evaluation and the charge/discharge graph (Ref) of the actual secondary battery.

In addition, the charge/discharge graph of the third secondary battery B3 for evaluation shows that due to a decrease in the voltage drop (IR Drop) at the start of charging, there is a difference between the charge/discharge graph of the actual secondary battery (Ref) and the charge/discharge graph of the second secondary battery B2 for evaluation.

As shown in FIGS. 7A to 7C, it can be confirmed that the charge/discharge graph of the second secondary battery B2 for evaluation is most similar to the charge/discharge graph (Ref) of the actual secondary battery.

Table 1 (below) shows the results of verifying suitability through the capacities of secondary batteries for evaluation (when the metal cap lengths are 1 cm, 1.5 cm, and 2 cm) compared to the capacity of an actual secondary battery. Here, the secondary batteries for evaluation may be secondary batteries having the same conditions as the secondary battery for evaluation, the voltages of which are measured over time, as shown in FIGS. 7A to 7C. However, the secondary batteries for evaluation in Table 1 have metal caps having lengths of 1 cm, 1.5 cm, and 2 cm. Hereinafter, the suitability result of the secondary battery for evaluation with a metal cap length of 1 cm is referred to as the suitability result of the first secondary battery B1 for evaluation, the suitability result of the secondary battery for evaluation with a metal cap length of 1.5 cm is referred to as the suitability result of the 1.5th secondary battery B1.5 for evaluation, and the suitability result of the secondary battery for evaluation with a metal cap length of 2 cm is referred to as the suitability result of the second secondary battery B2 for evaluation.

### Table 1

TABLE 1

| Cell | Constant voltage | Battery capacity | suitability |
|---|---|---|---|
| configuration | charge time (s) | (mAh) | (%) |
| Actual secondary | 265 | 4106 | — |
| battery (Ref) | | | |
| Metal cap length: | 299 | 3867 | 94 |
| 1 cm | | | |
| Metal cap length: | 227 | 4077 | 99.3 |
| 1.5 cm | | | |
| Metal cap length: | 293 | 4017 | 97.8 |
| 2 cm | | | |

Here, the suitability can be calculated by multiplying the value obtained by dividing the capacity of each secondary battery B1, B1.5, B2 for evaluation by the capacity of the actual secondary battery by 100. The suitability results show that the suitability of the 1.5th secondary battery B1.5 for evaluation and the suitability of the second secondary battery B2 for evaluation increase by 4-5% compared to the suitability of the first secondary battery B1 for evaluation. That is, it can be seen that from among the secondary batteries B1, B1.5, and B2 for evaluation, the secondary batteries with the metal cap lengths of 1.5 cm and 2 cm have similarly high suitability for capacity compared to the actual secondary battery.

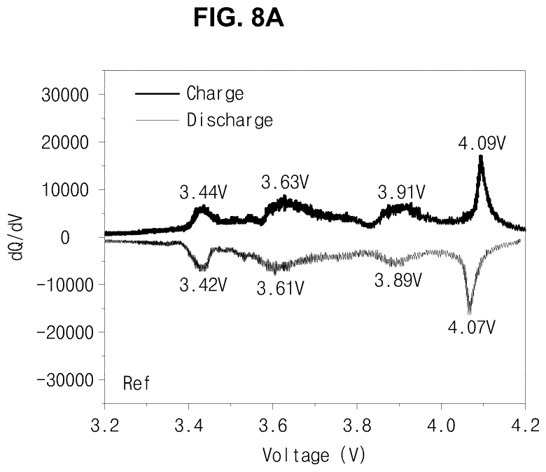

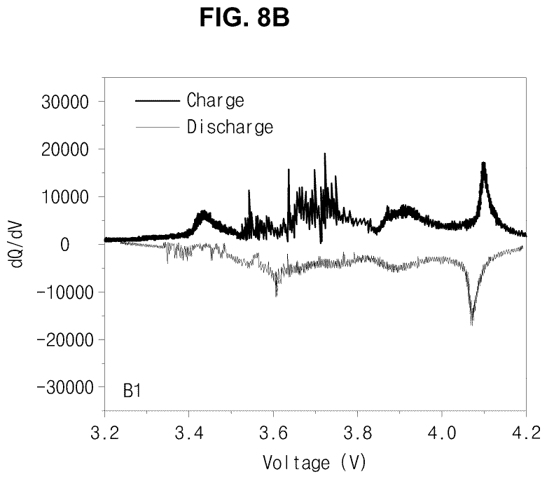

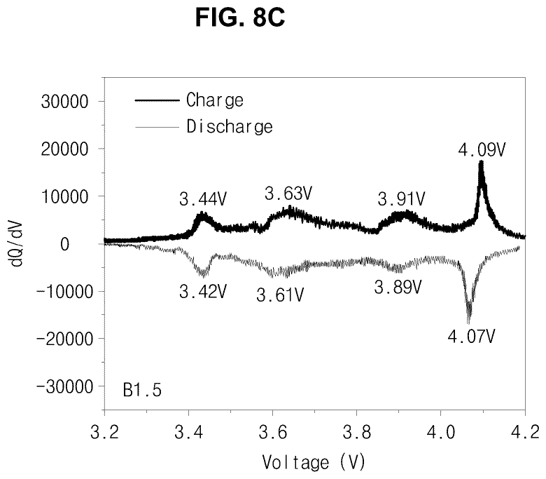

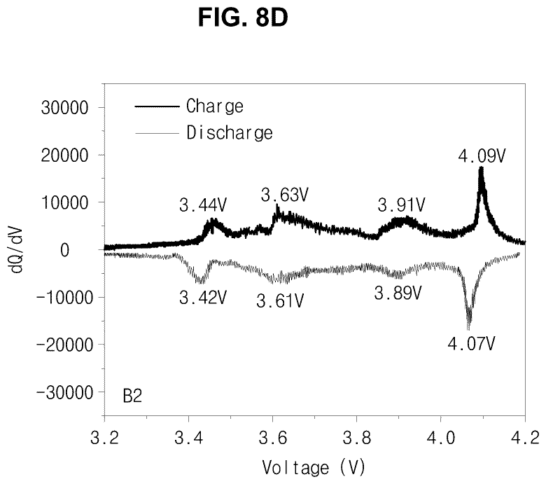

Additionally, FIGS. 8A to 8D show the capacity change rate according to the voltages for an actual secondary battery (Ref) and secondary batteries for evaluation (metal cap lengths of 1 cm, 1.5 cm, and 2 cm, respectively). Here, the secondary batteries for evaluation may be secondary batteries having the same conditions as the secondary battery for evaluation for which the voltages over time in FIGS. 7A to 7C were measured. However, the secondary batteries for evaluation in FIGS. 8A to 8D are when the metal cap lengths are 1 cm, 1.5 cm, and 2 cm. Hereinafter, the capacity change rate according to voltage of the secondary battery for evaluation having a metal cap length of 1 cm is referred to as the capacity change rate of the first secondary battery B1 for evaluation, the capacity change rate according to voltage of the secondary battery for evaluation having a metal cap length of 1.5 cm is referred to as the capacity change rate of the 1.5th secondary battery B1.5 for evaluation, and the capacity change rate according to voltage of the secondary battery for evaluation having a metal cap length of 2 cm is referred to as the capacity change rate of the second secondary battery B2 for evaluation.

FIG. 8A shows the capacity change rate according to the voltage change rate of an actual secondary battery. Here, the actual secondary battery (Ref) may have the same peak (the lowest point of the waveform and/or the highest point of the waveform) in the capacity change rate according to the voltage change rate if the same positive electrode, negative electrode, separator, and electrolyte are used. As shown in FIG. 8A, the actual secondary battery (Ref) showed peaks at 3.44 V, 3.63 V, 3.91 V, and 4.09 V during charging, and peaks at 3.42 V, 3.61 V, 3.89 V, and 4.07 V during discharging.

The capacity change rate according to the voltage change rate of the secondary battery B1, B1.5, B2 for evaluation may have the same peak when similar to that of the actual secondary battery (Ref). That is, when secondary batteries B1, B1.5, and B2 for evaluation have battery characteristics similar to the actual secondary battery (Ref) depending on the length of a metal cap, the capacity change rate may have the same peak.

The capacity change rate according to the voltage change rate of the first secondary battery B1 for evaluation shown in FIG. 8B shows unstable peaks during charging and discharging, suggesting that there is a difference from the actual secondary battery (Ref). In contrast, the capacity change rate according to the voltage change rate of the 1.5th secondary battery B1.5 for evaluation shown in FIG. 8C and the capacity change rate according to the voltage change rate of the second secondary battery B2 for evaluation shown in FIG. 8D show that the peaks during charging and discharging of the actual secondary battery (Ref) are located at the same voltage value.

Therefore, in the jig 200 for measuring three electrode voltages, the length of the metal cap for measuring charge/discharge voltage similar to that of an actually used secondary battery through the charge/discharge graph, suitability, and capacity change rate according to the voltage change rate, may be in a range of about 1.5 cm to about 2 cm.

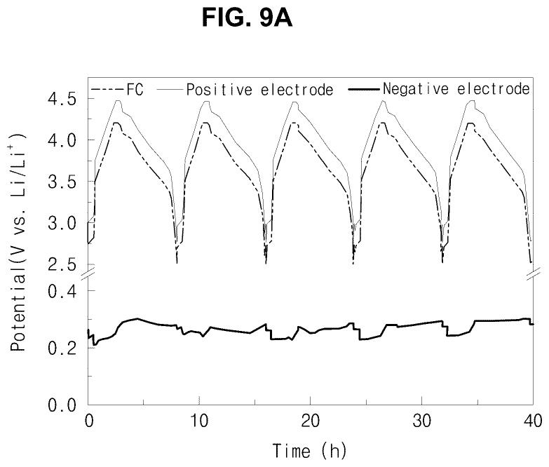

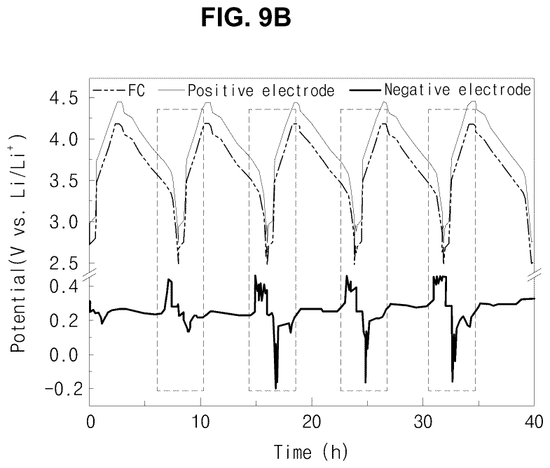

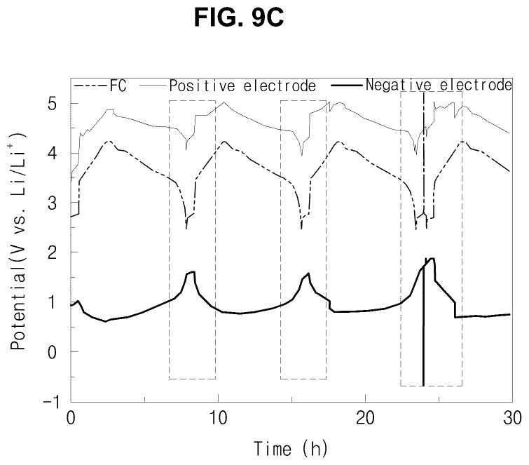

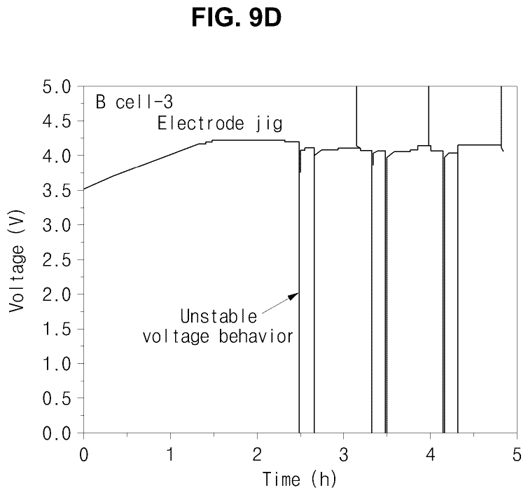

FIGS. 9A to 9D show the results (charge/discharge graph) of measuring the charge and discharge voltages over time according to the amount of electrolyte injected (0.8-1.4 ml) into a secondary battery for evaluation mounted on the jig for measuring three electrode voltages shown in FIG. 1. Here, the charge/discharge graph may include the charge/discharge graph (FC) of the entire secondary battery, the charge/discharge graph (positive electrode) of a positive electrode, and the charge/discharge graph (negative electrode) of a negative electrode.

Here, the actual secondary battery and the secondary batteries mounted on the jig 200 for measuring three electrode voltages (hereinafter referred to as “secondary batteries for evaluation”) are secondary batteries having the same capacity manufactured by the same manufacturing process. Hereinafter, the secondary battery for evaluation into which 1.0 ml of electrolyte is injected is referred to as a first-electrolyte secondary (Be1) battery for evaluation, the secondary battery for evaluation into which 1.2 ml of electrolyte is injected is referred to as a 1.2^{nd}-electrolyte secondary battery (Be1.2) for evaluation, and the secondary battery for evaluation into which 1.4 ml of electrolyte is injected is referred to as a 1.4th-electrolyte secondary battery (Be1.4) for evaluation.

The charge/discharge graphs shown in FIGS. 9A to 9D are measurements of charge/discharge voltage values over time when each of the secondary batteries for evaluation was subjected to five charge/discharge cycles. In addition, the actual secondary battery and the secondary batteries for evaluation were charged and discharged at voltages ranging from 2.5 V to 4.2 V, and were charged at 0.5 C and discharged at 0.2 C. Here, C may refer to the capacity of the battery.

FIG. 9A shows the charge/discharge graph of a first electrolyte secondary battery for evaluation (Be1), FIG. 9B shows the charge/discharge graph of a 1.2^{nd}-electrolyte secondary battery (Be1.2) for evaluation, and FIG. 9C show the charge/discharge graph of a 1.4th-electrolyte secondary battery (Be1.4) for evaluation. In addition, FIG. 9D shows the charge/discharge graph of a 0.8th-electrolyte secondary battery (Be0.8) for evaluation, into which less than 0.8 ml of electrolyte was injected.

As shown in FIG. 9B, the 1.2^{nd}-electrolyte secondary battery (Be1.2) for evaluation shows that the voltage fluctuates and is unstable in the late discharge and charge sections in the charge/discharge graph (FC) of the entire secondary battery and the charge/discharge graph (negative electrode) of the negative electrode. As shown in FIG. 9C, the 1.4th-electrolyte secondary battery (Be1.4) for evaluation shows that the charge/discharge graph (FC) of the entire secondary battery, the charge/discharge graph (positive electrode) of the positive electrode, and the charge/discharge graph (negative electrode) of the negative electrode show greater voltage changes in the late discharge and charge sections than in the 1.2^{nd}-electrolyte secondary battery (Be1.2) for evaluation. As shown in FIG. 9D, the 0.8th-electrolyte secondary battery (Be0.8) for evaluation has an insufficient amount of electrolyte, so the reference electrode is exposed to the outside of the electrolyte, and an unstable voltage behavior can be observed during charge/discharge voltage measurements due to electrolyte deficiency.

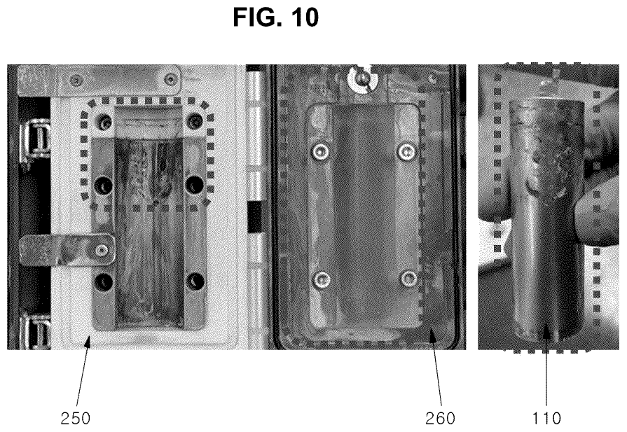

Here, as shown in the results of FIGS. 9A to 9D, it can be confirmed that the charge/discharge graph of the first-electrolyte secondary battery (Be1) for evaluation has a most stable profile. In addition, FIG. 10 shows the states of the secondary battery 110 for evaluation and the jig body 250 and the jig door 260 in the jig 200 for measuring three-electrode voltages after measuring the charge/discharge voltage over time after 3 ml of electrolyte is injected into the secondary battery for evaluation. As shown in FIG. 10, when more than 3 ml of electrolyte is injected, it is difficult to measure the charge and discharge voltage due to excessive injection, and due to electrolyte leakage, corrosion may occur on the surface of the jig 200 for measuring three electrode voltages and the secondary battery for evaluation. In addition, due to corrosion, resistance may occur to the secondary battery for evaluation, causing unstable charge/discharge voltage measurements, which reduces the reliability and reproducibility of the jig 200 for measuring three electrode voltages.

Therefore, in the jig 200 for measuring three electrode voltages, the amount of electrolyte injected to measure a charge/discharge voltage similar to that of an actually used secondary battery may be in a range of about 0.8 ml to about 1 ml.

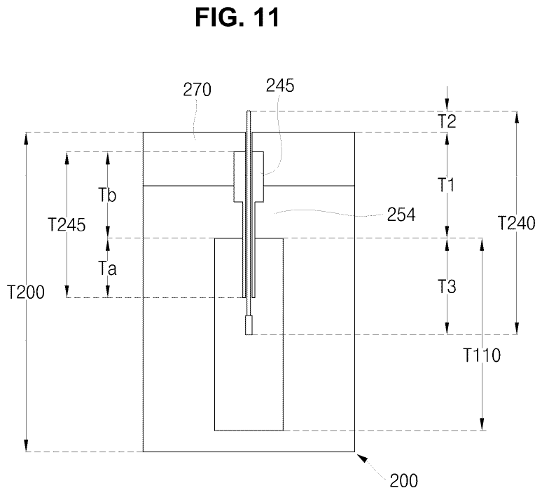

Referring to FIG. 11, a cross-sectional view showing the height of the reference electrode 240 and the height of the protective tube 245 according to the height of the secondary battery 110 and the jig 200 for measuring three electrode voltages is shown.

As shown in FIG. 11, the height (T240) of the reference electrode 240 may be the height of a first height (T1) that is the sum of the height of the hole cover 270 and the height of the top plate 254 in the jig body 250, a second height (T2) that is the height of the reference electrode 240 protruding upward from the hole cover 270, and a third height (T3) that is the height of the reference electrode 240 inserted into the interior of the secondary battery 110 for evaluation.

Here, the first height (T1) may be varied depending on the size of the jig 200 for measuring three electrode voltages, the height of the hole cover 270, and the height of the top plate 254 of the jig body 250.

In addition, the second height (T2) may be about 1 cm. The second height (T2), which is a value that can be associated with a three-electrode charger, may be changed in various ways, but as the length increases, the resistance may increase.

In addition, the third height (T3) may be in a range of about 30% to about 50% of the height (110T) of the secondary battery 110 for evaluation. For example, when the height (110T) of the secondary battery 110 for evaluation is 7 cm, the third height (T3) may be in a range of about 2.1-3.5 cm. When the third height (T3) is less than 30% of the height (110T) of the secondary battery 110 for evaluation, it may be difficult to maintain the optimal length in a range of 1.5-2 cm of the metal cap 242. In addition, when the third height (T3) exceeds 50% of the height (110T) of the secondary battery 110 for evaluation, the length of the reference electrode 240 may be unnecessarily increased, and thus, the resistance may increase, or the probability of deformation or insertion failure when the reference electrode 240 is inserted into the secondary battery 110 for evaluation may increase.

The height (T245) of the protective tube may be the sum of a first tube height (Ta), which is the height of the protective tube 245 inserted into the interior of the secondary battery 110 for evaluation, and a second tube height (Tb), which is the height from the top surface of the reference groove 270a of the hole cover 270 to the top surface of the secondary battery 110 for evaluation.

Here, the first tube height (Ta) may be in a range of about 20-30% of the height (110T) of the secondary battery 110 for evaluation. For example, when the height (110T) of the secondary battery 110 for evaluation is 7 cm, the first tube height (Ta) may be in a range of about 1.4-2.1 cm. When the first tube height (Ta) is less than 20% of the height (110T) of the secondary battery 110 for evaluation, it may be difficult to prevent damage to the secondary battery 110 for evaluation when the reference electrode 240 is inserted into the winding core of the secondary battery 110 for evaluation. In addition, when the first tube height (Ta) exceeds 30% of the height (110T) of the secondary battery 110 for evaluation, the secondary battery 110 for evaluation may expand due to charge and discharge, so that the winding core becomes narrow, and thus, the protective tube 245 may be affected or the metal cap 242 may not protrude downwardly from the protective tube 245.

The foregoing embodiments are only some embodiments of the jig for measuring three electrode voltages according to the present disclosure, which is not limited to the disclosed embodiments. It will be understood by a person skilled in the art that various changes in form and details may be made therein without departing from the spirit and scope of the present disclosure as defined by the following claims and their equivalents.

What is claimed is:

1. A jig for measuring three electrode voltages, the jig comprising:
a jig body having a receiving portion for mounting a secondary battery having an electrode assembly inside a case;
a jig door for opening or closing a first surface forming the receiving portion;
a positive electrode mounted on an upper portion of the receiving portion of the jig body, electrically connected to a positive electrode tab protruding toward an upper portion of the secondary battery mounted on the receiving portion, and having a portion protruding outwardly;
a negative electrode mounted on the receiving portion of the jig body, being in contact with and electrically connected to a conductive member electrically connected to the case of the secondary battery, and having a portion protruding outwardly; and
a reference electrode inserted into an electrolyte of a winding core of the electrode assembly of the secondary battery mounted in the receiving portion while extending through a top plate of the jig body and protruding to an upper portion of the jig body,
wherein the reference electrode comprises a metal wire and a metal cap wrapping around one side of the metal wire and is inserted into the winding core of the secondary battery, and
wherein a length of the metal cap is in a range of 15 mm to 20 mm.

2. The jig as claimed in claim 1, wherein a length of the reference electrode inserted into the secondary battery reaches 30% to 50% of a total height of the secondary battery.

3. The jig as claimed in claim 1, wherein the metal cap comprises lithium, and the metal wire comprises copper.

4. The jig as claimed in claim 1, wherein the top plate of the jig body has a reference groove having a depth from an upper surface to a lower side and a reference hole extending through the top plate from a center of the reference groove to the lower side.

5. The jig as claimed in claim 4, further comprising a protective tube,
wherein the protective tube comprises a body part having a diameter corresponding to an inner diameter of the reference groove and an extension part extending downwardly from a center of the body part and having a diameter corresponding to an inner diameter of the reference hole.

6. The jig as claimed in claim 5, wherein a length of the protective tube inserted into the secondary battery reaches 20% to 30% of a total height of the secondary battery.

7. The jig as claimed in claim 5, wherein the protective tube further comprises an O-ring on an outer surface of the body part.

8. The jig as claimed in claim 5, wherein the protective tube further comprises a penetration pipe extending between upper and lower sides of the top plate, and
wherein the reference electrode protrudes upwardly and downwardly through the penetration pipe of the protective tube.

9. The jig as claimed in claim 5, further comprising a hole cover coupled to an upper side of the top plate and having a reference hole for exposing and receiving a portion of the reference electrode to the outside.

10. The jig as claimed in claim 9, wherein the hole cover has a reference groove having a depth upward from a lower surface and a reference hole extending through the hole cover upwardly from a center of the reference groove of the hole cover.

11. The jig as claimed in claim 10, wherein the protective tube comprises a body part between the top plate of the jig body and the hole cover.

12. The jig as claimed in claim 1, wherein the jig door has a flat plate shape, one edge of an inner surface is coupled to the jig body by a hinge, and a first surface of the jig body is configured to be opened and closed by rotation.

13. The jig as claimed in claim 12, wherein the jig door has a receiving portion for receiving a portion of the secondary battery mounted in the receiving portion of the jig body on an inner surface.

14. The jig as claimed in claim 12, further comprising rubber packing provided along an inner edge of the jig door, and
wherein the rubber packing is between the inner surface of the jig door and the first surface of the jig body.

15. The jig as claimed in claim 12, wherein, in the jig door, a spring press is provided on an inner surface in contact with the positive electrode and the positive electrode tab of the secondary battery.

16. The jig as claimed in claim 1, wherein the jig body has a rectangular parallelepiped shape.

17. The jig as claimed in claim 1, wherein the conductive member covers an inner surface of the receiving portion and extends to partially cover the first surface of the jig body.

18. The jig as claimed in claim 1, wherein the positive electrode is mounted on the first surface on an upper side of the receiving portion of the jig body.

19. The jig as claimed in claim 1, wherein an electrolyte is added into the case of the secondary battery, and
wherein an amount of electrolyte added is in a range of 0.8 ml to 1.0 ml.
